(19) United States
(12) Patent Application Publication
(10) Pub. No.: US 2018/0211984 A1
(43) Pub. Date: Jul. 26, 2018

(54) ARRAY SUBSTRATE AND METHOD FOR MANUFACTURING THE SAME

(71) Applicant: Shenzhen China Star Optoelectronics Technology Co. , Ltd., Shenzhen, Guangdong (CN)

(72) Inventor: Mian Zeng, Shenzhen, Guangdong (CN)

(73) Assignee: Shenzhen China Star Optoelectronics Technology Co., Ltd., Shenzhen, Guangdong (CN)

(21) Appl. No.: 15/500,125

(22) PCT Filed: Jan. 18, 2017
(86) PCT No.: PCT/CN2017/071600

§ 371 Date: Dec. 7, 2017

(30) Foreign Application Priority Data
Aug. 31, 2016 (CN) 201610799421.4

(51) Int. Cl. H01L 27/12; H01L 51/05

(52) U.S. Cl. CPC H01L 27/1251; H01L 51/0558; H01L 27/1225; H01L 27/1259

(57) ABSTRACT

Disclosed are an array substrate and a method for manufacturing the same. The array substrate includes a transmission gate structure having an upper thin film transistor and a lower thin film transistor. An active layer of the lower TFT is the first active layer, and an active layer of the upper TFT is the second active layer. The first active layer and the second active layer are provided on two sides of a source and drain layer, respectively, and share source and drain electrodes. Compared with the prior art, such structure is simpler, and furthermore it facilitates simplification of a manufacturing process of the transmission gate structure and improves a success rate of preparation thereof.

### CROSS-REFERENCE TO RELATED APPLICATIONS

This application claims the priority of Chinese patent application CN 201610799421.4, entitled “Array substrate and method for manufacturing the same” and filed on Aug. 31, 2016, the entirety of which is incorporated herein by reference.

### FIELD OF THE INVENTION

The present disclosure relates to the technical field of liquid crystal display, and in particular, to an array substrate and a method for manufacturing the same.

### BACKGROUND OF THE INVENTION

Liquid crystal display (LCD) panels have advantages such as thin profile, low power consumption, and no radiation, and thus have been widely used in LCD display devices, mobile phones, personal digital assistants, etc.

A complementary metal oxide semiconductor (CMOS) comprises a positive channel metal oxide semiconductor (PMOS) and a negative channel metal oxide semiconductor (NMOS). A CMOS circuit serves as a most basic circuit structure of a drive integrated circuit (IC).

A CMOS transmission gate is formed by a parallel connection of a p-channel metal-oxide-semiconductor field-effect transistor (MOSFET) and an n-channel MOSFET. In addition to being used as a switch to transmit an analog signal, the CMOS transmission gate also can be used as a basic unit circuit of various logic circuits.

Due to the complementary structure of the CMOS, there is no loss of threshold value, when a CMOS transmission gate transmits a high/low level signal, i.e., input and output signals are in good agreement. Moreover, on-resistance of the CMOS transmission gate is relatively low, and can be approximately constant. In addition, a drain and a source of the CMOS transmission gate are interchangeable, and therefore the CMOS transmission gate is bidirectional. If applied in a GOA (Gate On Array) circuit, the CMOS transmission gate can be used as a switch for control of bidirectional scanning in a panel.

In current display panels, most of substrates are made of glass or polyethylene naphthalate (PEN), etc., and active elements formed thereon are substantially N-type amorphous silicon (a-Si) thin film transistors (TFTs), not P-type TFT structures. In Low Temperature Poly-silicon (LTPS) technology, a-Si can be converted to Poly Si by excimer laser annealing (ELA) and the like, and a P-type TFT and an N-type TFT can be formed by using different types of doping at a channel. A CMOS-like complementary thin film transistor (CTFT) can thus be formed. However, a manufacturing process of a CTFT is complex, and preparation cost thereof is relatively high.

### SUMMARY OF THE INVENTION

The technical problem to be solved by the present disclosure is to provide an array substrate and a method for manufacturing the same, so as to simplify a manufacturing process of a CTFT and improve a success rate of preparation thereof.

In order to solve the above technical problem, the present disclosure provides the following technical solutions.

In one aspect, the present disclosure provides an array substrate.

The array substrate of the present disclosure comprises a transmission gate structure which comprises from bottom to top a first gate provided on a substrate, a first gate insulating layer provided on the first gate and completely covering the first gate, a first active layer provided on the first gate insulating layer and opposite to the first gate, an insulating layer provided on the first active layer, a source and drain layer provided on the insulating layer and electrically connected to the first active layer by means of a via hole located on the insulating layer, a second active layer provided on the source and drain layer, a second gate insulating layer provided on the second active layer and completely covering the second active layer, and a second gate provided on the second gate insulating layer and opposite to the second active layer.

Preferably, the first active layer is an N-type active layer and the second active layer is a P-type active layer.

Preferably, the insulating layer comprises an etch stop layer and/or a planarization layer.

Preferably, when the insulating layer comprises an etch stop layer and a planarization layer, the etch stop layer is provided on the first active layer, and the planarization layer is provided on the etch stop layer.

Preferably, the etch stop layer is made of a silicon nitride and/or a silicon oxide.

In the array substrate provided by the present disclosure, the transmission gate structure comprises an upper TFT and a lower TFT. An active layer of the lower TFT is the first active layer, and an active layer of the upper TFT is the second active layer. The first active layer and the second active layer are provided on two sides of the source and drain layer, respectively, and share source and drain electrodes. Compared with the prior art, such structure is simpler, and furthermore it facilitates simplification of a manufacturing process of the transmission gate structure and improves a success rate of preparation thereof.

The present disclosure further provides a method for manufacturing an array substrate. The method comprises following steps.

In step S1, a substrate is obtained.

In step S2, a first gate is formed on the substrate.

In step S3, a first gate insulating layer completely covering the first gate is formed on the first gate.

In step S4, a first active layer is formed on the first gate insulating layer, the first active layer being opposite to the first gate.

In step S5, an insulating layer is formed on the first active layer, and the insulating layer is patterned to form a via hole.

In step S6, a source and drain layer is formed on the insulating layer, the source and drain layer being electrically connected to the first active layer by means of the via hole.

In step S7, a second active layer is formed on the source and drain layer.

In step S8, a second gate insulating layer completely covering the second active layer is formed on the second active layer.

In step S9, a second gate opposite to the second active layer is formed on the second gate insulating layer.

Preferably, the first active layer is an N-type active layer and the second active layer is a P-type active layer. The first active layer is made of a metal oxide material, and the second active layer is made of a P-type organic semiconductor material.

Preferably, the insulating layer comprises an etch stop layer and/or a planarization layer.

Preferably, when the insulating layer comprises an etch stop layer and a planarization layer, the step S5 comprises following steps.

In step S51, an etch stop layer covering the first active layer is formed on the first active layer.

In step S52, a planarization layer covering the etch stop layer is formed on the etch stop layer.

In step S53, the etch stop layer and the planarization layer are patterned to form a via hole penetrating both the planarization layer and the etch stop layer.

Preferably, the etch stop layer is made of a silicon nitride and/or a silicon oxide.

In the array substrate provided by the present disclosure, the transmission gate structure comprises an upper TFT and a lower TFT. An active layer of the lower TFT is the first active layer, and an active layer of the upper TFT is the second active layer. The first active layer and the second active layer are provided on two sides of the source and drain layer, respectively, and share source and drain electrodes. Compared with the prior art, such structure is simpler, and furthermore it facilitates simplification of a manufacturing process of the transmission gate structure and improves a success rate of preparation thereof.

### BRIEF DESCRIPTION OF THE DRAWINGS

The drawings necessary for explaining the embodiments are introduced briefly below to illustrate the technical solutions of the embodiments of the present disclosure or the prior art more clearly. Obviously, the drawings below are only for explaining the embodiments of the present disclosure. For those skilled in the art, other drawings may be obtained based on these drawings without the exercise of inventive faculty. In the drawings:

FIG. 1 schematically shows a structure of a first array substrate according to an embodiment of the present disclosure;

FIG. 2 schematically shows a structure of a second array substrate according to an embodiment of the present disclosure; and

FIG. 3 schematically shows a structure of a third array substrate according to an embodiment of the present disclosure.

List of reference numbers: 1—Substrate; 2—First gate; 3—First gate insulating layer; 4—N-type active layer; 5—Etch stop layer; 6—Via hole; 7—Source and drain layer; 8—P-type active layer; 9—Second gate insulating layer; 10—Second gate; and 11—Planarization layer.

### DETAILED DESCRIPTION OF THE EMBODIMENTS

The technical solutions in the embodiments of the present disclosure will be described clearly and completely hereinafter with reference to the accompanying drawings. Obviously, the described embodiments are a part of embodiments of the present disclosure, not all embodiments thereof. Based on the embodiments in the present disclosure, all other embodiments obtained by those skilled in the art without the exercise of inventive faculty shall fall within the scope of the present disclosure.

The present embodiment provides an array substrate in which a structure of a CTFT transmission gate in the prior art is optimized so as to be integrated on an array substrate and other substrates like a glass substrate or a PEN substrate by making the most of the existing manufacturing progress, so that the array substrate can be more widely used and costs of products using such array substrate can be reduced.

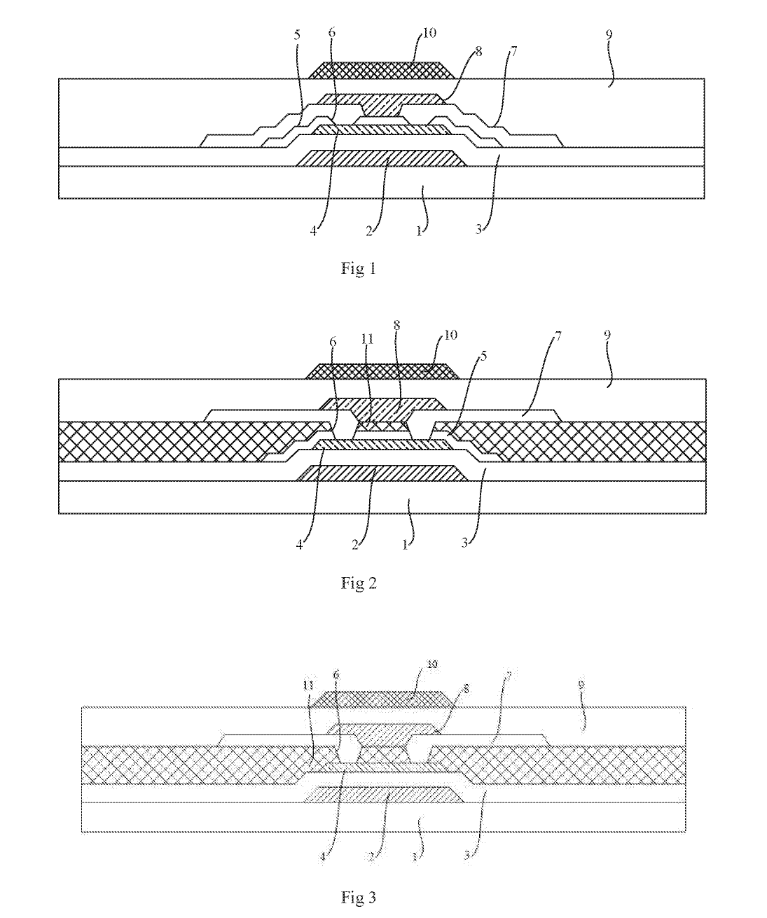

As shown in FIG. 1, a CTFT, as a transmission gate circuit structure, is optimized by the present disclosure. The CTFT comprises from bottom to top a first gate 2 provided on a substrate 1, a first gate insulating layer 3 provided on the first gate 2 and completely covering the first gate 2, an N-type active layer 4 provided on the first gate insulating layer 3 and opposite to the first gate 2, an insulating layer (in the embodiment shown in FIG. 1, the insulating layer is an etch stop layer 5) provided on the N-type active layer 4, a source and drain layer 7 provided on the insulating layer and electrically connected to the N-type active layer 4 by means of a via hole 6 located on the insulating layer, a P-type active layer 8 provided on the source and drain layer 7, a second gate insulating layer 9 provided on the P-type active layer 8 and completely covering the P-type active layer 8, and a second gate 10 provided on the second gate insulating layer 9 and opposite to the P-type active layer 8.

Obviously, in the array substrate provided by the present embodiment, each CTFT comprises an upper TFT and a lower TFT. An active layer of the lower TFT is the N-type active layer 4, and thus the lower TFT is an N-type TFT. An active layer of the upper TFT is the P-type active layer 8, and thus the upper TFT is a P-type TFT. The N-type active layer 4 and the P-type active layer 8 are provided on two sides of the source and drain layer 7, respectively, and share source and drain electrodes. Compared with the prior art, such structure is simpler, and furthermore it facilitates simplification of a manufacturing process of the CTFT and improves a success rate of preparation thereof.

Further, in order to manufacture the aforesaid array substrate, the present embodiment further provides a corresponding manufacturing method which comprises following steps.

In step S1, a substrate 1 is obtained.

In step S2, a first gate 2 is formed on the substrate 1.

In step S3, a first gate insulating layer 3 completely covering the first gate 2 is formed on the first gate 2.

In step S4, an N-type active layer 4 is formed on the first gate insulating layer 3, the N-type active layer 4 being opposite to the first gate 2.

In step S5, an insulating layer is formed on the N-type active layer 4, and the insulating layer is patterned to form a via hole 6.

In step S6, a source and drain layer 7 is formed on the insulating layer, the source and drain layer 7 being electrically connected to the N-type active layer by means of the via hole 6.

In step S7, a P-type active layer 8 is formed on the source and drain layer 7.

In step S8, a second gate insulating layer 9 completely covering the P-type active layer 8 is formed on the P-type active layer 8.

In step S9, a second gate 10 opposite to the P-type active layer 8 is formed on the second gate insulating layer 9.

In view of the instability of an organic material and the susceptibility thereof to the environment, in a structure described in the present application, a manufacturing process of a P-type TFT is arranged after that of an NTFT, and a top-gate bottom-contact structure is used. In this way, it is ensured that properties of organic semiconductors of a P-type TFT device are not affected by a manufacturing process thereof.

In the present embodiment, the insulating layer can comprise merely an etch stop layer 5 as shown in FIG. 1, or merely a planarization layer 11 as shown in FIG. 3, or comprises an etch stop layer 5 and a planarization layer 11 overlying the etch stop layer 5 as shown in FIG. 2.

Based on the three types of insulating layers, the present embodiment provides three specific types of array substrates and manufacturing methods thereof. Specific details are as follows.

FIG. 1 shows a structure of a CTFT on a first array substrate. The CTFT comprises a P-type TFT with a top-gate bottom-contact structure and an N-type TFT with an etch stop layer 5. A manufacturing method of the CTFT is as follows.

Firstly, a gate metal layer is deposited on a substrate 1 by sputtering (using for example, Mo/Al/Mo or Cu/Ti material). After steps of exposure, development, etching, and removing, a first gate 2 is formed as a gate electrode of an N-type oxide TFT. The substrate 1 in the present embodiment can be made of a material such as glass and polyethylene naphthalate (PET).

Subsequently, a first gate insulating layer 3 is formed on the first gate 2 by chemical vapor deposition (CVD) or coating. After that, a layer of Indium Gallium Zinc Oxide (IGZO) or other N-type metal oxide semiconductor material is formed on the first gate insulating layer 3. Similarly, after steps of exposure, development, etching, and removing, an N-type active layer 4 is formed. Next, an etch stop layer 5 is formed on the N-type active layer 4. The etch stop layer 5 is generally made of a silicon nitride (SiNx) and/or a silicon oxide (SiOx). Moreover, the etch stop layer 5 is patterned to form a via hole 6 which is connected to a source and drain layer 7.

Then, a source and drain electrode metal layer is formed on the etch stop layer 5 by sputtering (using for example, Mo/Al/Mo or Cu/Ti material). After steps of exposure, development, etching, and removing, a source and drain layer 7 is formed as common source and drain electrodes of the N-type TFT and the P-type TFT.

Next, a P-type active layer 8 is prepared by coating a P-type organic semiconductor material (for example, pentacene and other materials) onto the substrate 1 and forming a pattern of the P-type active layer 8 by photolithography. Thereafter, a protective layer is formed by CVD or coating. The protective layer can serve as a gate insulating layer of the P-type TFT, i.e., a second gate insulating layer 9.

Finally, a top gate electrode structure, i.e., a second gate 10, of the P-type TFT is prepared on the second gate insulating layer 9 by photolithography or vapor deposition. Thus, the CTFT transmission gate structure shown in FIG. 1 is completed. The description of subsequent preparation of electrical connection and packaging of the protective layer is omitted.

Obviously, an insulating layer in the CTFT of the array substrate as shown in FIG. 1 comprises merely the etch stop layer 5. As to the insulating layer comprising the etch stop layer 5 and the planarization layer 11, as shown in FIG. 2, a CTFT also comprises a P-type TFT with a top-gate bottom-contact structure and an N-type TFT with an etch stop layer 5.

A structure of the CTFT shown in FIG. 2 is an improved structure of FIG. 1. When a P-type active layer 8 is spin coated or coated, in order to ensure the flatness of a substrate surface thereof, a planarization layer 11 is coated on a surface of the etch stop layer 5 after the etch stop layer 5 is formed. The planarization layer 11 is usually made of an organic material, and has a function of planarization. Then, the etch stop layer 5 and the planarization layer 11 are patterned together to form a via hole 6 by means of which a source and drain layer 7 is in contact with an N-type active layer 4.

In this way, it is ensured that a lower surface of the P-type active layer 8 is relatively flat when the P-type active layer 8 is spin-coated or coated after the source and drain layer 7 is formed. Besides, adhesiveness of the P-type active layer 8 and the lower surface thereof is increased, and interface properties thereof are improved. That is, it can help to optimize properties of a P-type TFT device to be prepared subsequently.

Obviously, the insulating layer can comprise merely a planarization layer 11. As shown in FIG. 3, a CTFT of the array substrate also comprises a P-type TFT with a top-gate bottom-contact structure and an N-type TFT with an etch stop layer. The structure of the CTFT shown in FIG. 3 is an improved structure of FIG. 2. A planarization layer 11 in FIG. 3 can serve as either an etch stop layer for protecting an N-type active layer 4, or a planarization layer for improving a spin coating or coating effect of a P-type active layer 8. In this way, a process for preparing the etch stop layer can be saved, costs of manufacture of the array substrate is saved, and a success rate of preparation of the array substrate and a product yield can be improved.

It should be noted that the N-type active layer and the P-type active layer of the present disclosure can be interchanged with each other, which does not affect the technical solutions described in various embodiments thereof.

The preferred embodiments of the present disclosure are stated hereinabove, but the protection scope of the present disclosure is not limited by the embodiments. Any changes or substitutes readily conceivable for those skilled in the art within the technical scope disclosed herein shall be covered by the protection scope of the present disclosure. Therefore, the protection scope of the present disclosure shall be determined by the scope as defined in the claims.

1. An array substrate, comprising a transmission gate structure which comprises from bottom to top:
a first gate provided on a substrate;
a first gate insulating layer provided on the first gate and completely covering the first gate;
a first active layer provided on the first gate insulating layer and opposite to the first gate;
an insulating layer provided on the first active layer;
a source and drain layer, provided on the insulating layer and electrically connected to the first active layer by means of a via hole located on the insulating layer;
a second active layer provided on the source and drain layer;
a second gate insulating layer provided on the second active layer and completely covering the second active layer; and
a second gate provided on the second gate insulating layer and opposite to the second active layer.

2. The array substrate according to claim 1, wherein the first active layer is an N-type active layer and the second active layer is a P-type active layer.

3. The array substrate according to claim 1, wherein the insulating layer comprises an etch stop layer and/or a planarization layer.

4. The array substrate according to claim 3, wherein when the insulating layer comprises an etch stop layer and a planarization layer, the etch stop layer being provided on the first active layer, and the planarization layer being provided on the etch stop layer.

5. The array substrate according to claim 3, wherein the etch stop layer is made of a silicon nitride and/or a silicon oxide.

6. A method for manufacturing an array substrate, wherein the method comprises following steps of:
step S1, obtaining a substrate;
step S2, forming a first gate on the substrate;
step S3, forming a first gate insulating layer completely covering the first gate on the first gate;
step S4, forming a first active layer on the first gate insulating layer, the first active layer being opposite to the first gate;
step S5, forming an insulating layer on the first active layer and patterning the insulating layer to form a via hole;
step S6, forming a source and drain layer on the insulating layer, the source and drain layer being electrically connected to the first active layer by means of the via hole;
step S7, forming a second active layer on the source and drain layer;
step S8, forming a second gate insulating layer completely covering the second active layer on the second active layer; and
step S9, forming a second gate opposite to the second active layer on the second gate insulating layer.

7. The method according to claim 6, wherein the first active layer is an N-type active layer and the second active layer is a P-type active layer; and
wherein the first active layer is made of a metal oxide material, and the second active layer is made of a P-type organic semiconductor material.

8. The method according to claim 6, the insulating layer comprises an etch stop layer and/or a planarization layer.

9. The method according to claim 8, wherein when the insulating layer comprises an etch stop layer and a planarization layer, the step S5 comprises:
step S51, forming an etch stop layer covering the first active layer on the first active layer;
step S52, forming a planarization layer covering the etch stop layer on the etch stop layer; and
step S53, patterning the etch stop layer and the planarization layer to form a via hole penetrating both the planarization layer and the etch stop layer.

10. The method according to claim 8, wherein the etch stop layer is made of a silicon nitride and/or a silicon oxide.
